(19) United States
(12) Patent Application Publication
(10) Pub. No.: US 2013/0174411 A1
(43) Pub. Date: Jul. 11, 2013

(54) DISASSEMBLY METHOD AND DISASSEMBLY DEVICE FOR DISPLAY DEVICE

(71) Applicant: Panasonic Corporation, Osaka (JP)

(72) Inventor: Hiroshi IWAMOTO, Osaka (JP)

(73) Assignee: PANASONIC CORPORATION, Osaka (JP)

(21) Appl. No.: 13/784,409

(22) Filed: Mar. 4, 2013

Related U.S. Application Data
(63) Continuation of application No. PCT/JP2012/002675, filed on Apr. 18, 2012.

(30) Foreign Application Priority Data
Oct. 21, 2011 (JP) 2011-231387

(51) Int. Cl. H05K 13/00

(52) U.S. Cl. CPC H05K 13/00
USPC 29/592.1; 29/762

(57) ABSTRACT

The present disclosure relates to disassembly of a display device having a panel module in which a panel is joined to a support member by joint member (3) and a circuit board is disposed on a rear side of the support member. The joint member of the panel module is immersed into heated heating medium (12) with the panel module being held by holder (10), this joint member is heated while heat transmitted to the support member at the time of heating is conducted to holder (10) and dissipated, and the panel and the support member are then separated.

### TECHNICAL FIELD

The present disclosure relates to a disassembly method and a disassembly device for separating a panel from a support member in a display device such as a plasma display device.

### BACKGROUND ART

In recent years, as display devices appropriate for slimming and upsizing, liquid crystal display devices using liquid crystal display panels and plasma display devices using plasma display panels (hereinafter abbreviated to a PDP) have been mass-produced and sales thereof have abruptly been expanded.

For example, a PDP is configured by a pair of glass substrates, which are a front plate and a rear plate. The front plate is formed with a display electrode, a dielectric layer, a protective layer, and the like on a front glass substrate. On the other hand, the rear plate is formed with an address electrode, a barrier rib, a phosphor layer, and the like on a rear glass substrate. The front plate and the rear plate are arranged as opposed to each other so as to form a minute discharge space therebetween, and peripheral edges of the front glass substrate and the rear glass substrate are sealed by a sealing member. Further, the discharge space is filled with a discharge gas formed by mixing neon (Ne), xenon (Xe), and the like.

A metal support plate as a chassis member has been pasted to the rear surface of the rear plate of the PDP with a joint member such as a thermally conductive sheet with bonding properties or a bonding agent interposed therebetween. The metal support plate has a function as the chassis member as well as a function as a heat sink. The chassis member is used to be attached with a circuit board mounted with a drive circuit for driving the PDP, and the heat sink is used to efficiently dissipate heat generated by the drive of the PDP. Further, the plasma display device is mounted with a front frame and a back cover for protecting the PDP and the circuit board.

With such diffusion of display devices like plasma display devices in great amount, a display device as a waste object attributable to a defect generated in a manufacturing process and a display device as a waste object at the end of its product life have been required to be disassembled into such a form as to allow recycling of a variety of materials at low cost.

For example, disassembling the plasma display device into a recyclable form requires separation of the PDP mainly made up of the glass substrates, the metal-made chassis member as a support member of the PDP, and the circuit board mounted with a variety of electronic components.

As conventional methods for separating the PDP and the metal-made chassis member, there are known a method for separation by decreasing bonding strength of the joint member by heating (refer to PTLs 1 and 2, for example) and a method for separation of the joint member by mechanical physical means (refer to PTL 3, for example).

### CITATION LIST

### Patent Literatures

PTL1: Unexamined Japanese Patent Publication No. 2005-11092

PTL2: Unexamined Japanese Patent Publication No. 2005-116346

PTL3: Unexamined Japanese Patent Publication No. 2005-129318

### SUMMARY

A disassembly method for a display device of the present disclosure relates to a disassembly method for a display device having a panel module in which a panel is joined to a support member by a joint member and a circuit board is disposed on a rear side of the support member. The joint member of the panel module is immersed into a heated heating medium with the panel module being held by a holder including a heat radiating material, and the joint member is heated while heat transmitted to the support member at the time of heating is conducted to the holder and dissipated. Subsequently, the panel and the support member are separated.

Further, a disassembly device of the present disclosure relates to a disassembly device for a display device having a panel module in which a panel is joined to a support member by a joint member and a circuit board is disposed on the rear side of the support member. The disassembly device includes: a holder made of a heat radiating material and serving to hold a panel module; lifting means for moving up and down the holder; an immersion bath, inside which a heating medium is housed; and heating means arranged at the bottom of the immersion bath and serving to heat the heating medium. The joint member of the panel module is immersed into a heated heating medium with the panel module being held by a holder including a heat radiating material, and the joint member is heated while heat transmitted to the support member at the time of heating is conducted to the holder and dissipated.

### BRIEF DESCRIPTION OF DRAWINGS

FIG. 1 is an exploded perspective view showing an overall configuration of a plasma display device in an embodiment of the present disclosure.

FIG. 2 is a schematic sectional view of a panel module of the plasma display device in the embodiment of the present disclosure.

FIG. 3A is a schematic sectional view explaining disassembly of the plasma display device in the embodiment of the present disclosure.

FIG. 3B is a schematic sectional view explaining disassembly of the plasma display device in the embodiment of the present disclosure.

FIG. 3C is a schematic sectional view explaining disassembly of the plasma display device in the embodiment of the present disclosure.

### DESCRIPTION OF EMBODIMENT

Hereinafter, a disassembly method and a disassembly device for a display device according to an embodiment of the present invention will be described by taking a plasma display device as an example.

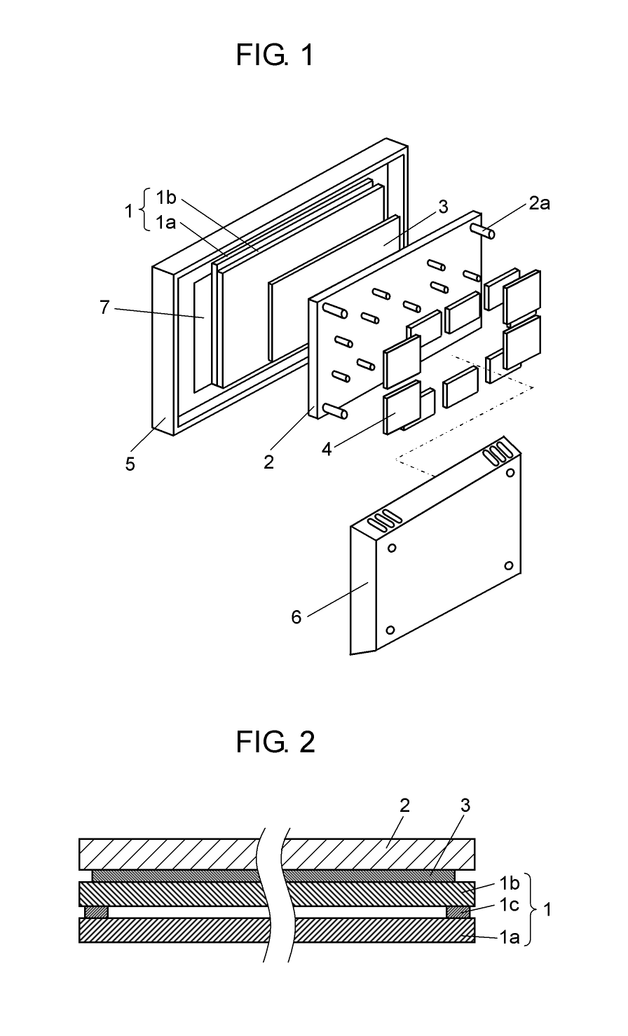

FIG. 1 is an exploded perspective view showing an overall configuration of the plasma display device.

As shown in FIG. 1, the plasma display device is provided with a panel module and a housing where this panel module is housed.

The panel module has PDP 1, chassis member 2, and thermally conductive joint member 3 that joins PDP 1 with chassis member 2. PDP 1 has front glass substrate 1a and rear glass substrate 1b. Chassis member 2 is a metal-made support member also serving as a heat sink, such as aluminum. Chassis member 2 is joined with rear glass substrate 1b with joint member 3 interposed therebetween. The rear side of chassis member 2 of this panel module is arranged with circuit board 4 constituting a circuit block for driving PDP 1.

The housing has front frame 5 and back cover 6. The panel module is arranged between front frame 5 and back cover 6, and housed inside the housing. Further, front frame 5 has an opening, and at this opening, front cover 7 is arranged, serving as an optical filter and also protecting the PDP 1. This front cover 7 is made of glass or the like for suppressing unnecessary radiation of an electromagnetic wave.

Further, fixing pin 2a is provided on the rear side of chassis member 2 where circuit board 4 is arranged, and circuit board 4 is attached to this fixing pin 2a.

FIG. 2 is a schematic sectional view of a panel module of the plasma display device in the embodiment of the present disclosure.

As shown in FIG. 2, peripheries of front glass substrate 1a and rear glass substrate 1b are sealed and joined by sealing member 1c, thereby constituting PDP 1. Further, the rear side of rear glass substrate 1b is arranged with joint member 3 having, on its both surfaces, bonding properties or welding properties (hereinafter collectively referred to as joining properties), and chassis member 2 is joined with PDP 1 with this joint member 3 interposed therebetween. Joint member 3 is joined almost over rear glass substrate 1b of PDP 1, and is also joined almost over chassis member 2.

This joint member 3 serves as a thermally conductive sheet. Joint member 3 dissipates heat generated heat from PDP 1 to chassis member 2, thereby to suppress a temperature rise of the whole of PDP 1, and also suppress a local temperature rise. As a result, it is possible to suppress cracking in front glass substrate 1a and rear glass substrate 1b, so as to suppress deterioration in image quality of image display.

Further, as joint member 3, a thermally conductive sheet is used which was obtained by kneading a substrate mainly composed of an acrylic copolymer with a metallic fire-retardant, urethane foam and the like and then sheeting the kneaded matter. Both surfaces of the thermally conductive sheet have adhesion properties, and rear glass substrate 1b is adhesively joined with chassis member 2 via both surfaces of the thermally conductive sheet. Herein, sheet-like joint member 3 mainly composed of an acrylic copolymer has a characteristic of its adhesion properties decreasing or being lost at a temperature of not lower than 200° C., resulting in decreased joining strength.

Next, a disassembly method and a disassembly device according to the present disclosure will be described.

In a disassembly method for a plasma display device shown in FIG. 1, first, front frame 5 and back cover 6 are separated, and then PDP 1 and chassis member 2 fixed with circuit board 4 are separated. With PDP 1 and chassis member 2 joined with joint member 3 interposed therebetween, those are separated as follows. Joint member 3 which joins chassis member 2 with PDP 1 is heated, thereby to decrease or eliminate the adhesion properties of joint member 3. This leads to a decrease in joining strength between PDP 1 and chassis member 2, thereby allowing separation of PDP 1 from chassis member 2.

Next, after separation of front glass substrate 1a and rear glass substrate 1b of PDP 1, the constituents such as the electrodes and the dielectric layer formed on the respective glass substrate are removed, and the glass substrates are collected and then recycled by such a method as re-dissolution.

Further, as for chassis member 2 with circuit board 4, it is crushed as it is and then separated and classified into respective kinds of materials such as a metal and a resin, to be recycled or disposed.

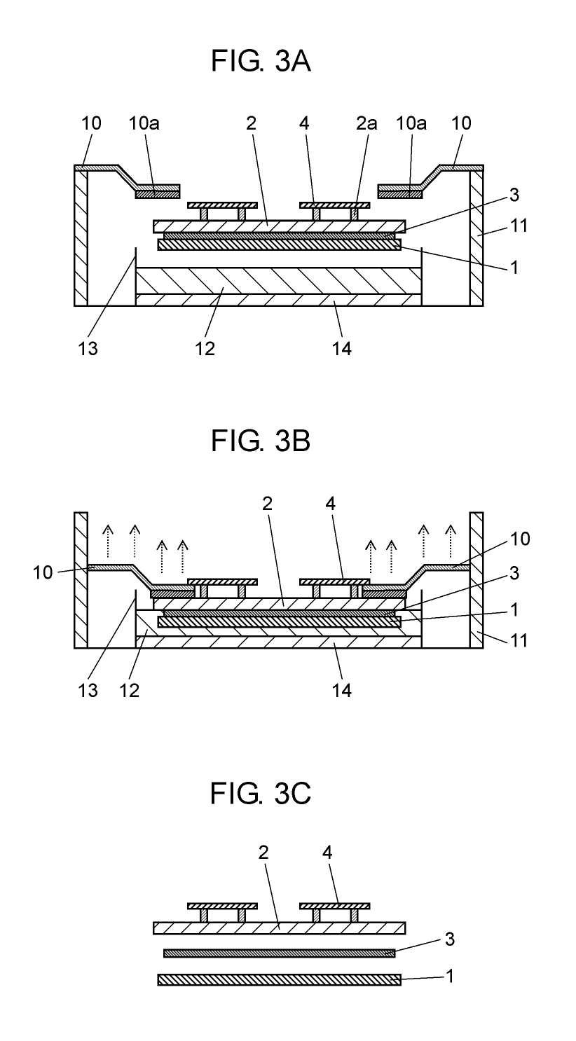

Next, a disassembly method for separating PDP 1 and chassis member 2 will hereinafter be described in detail with reference to FIGS. 3A to 3C.

FIGS. 3A to 3C are schematic sectional views explaining disassembly of the plasma display device in the embodiment of the present disclosure.

As shown in FIG. 3A, the disassembly device has: thermally conductive elastic body 10a made of a heat radiating material such as a metal material; holder 10 for holding a panel module; lifting means 11 for moving up and down holder 10; immersion bath 13, inside which heating medium 12 is housed; and heating means 14 arranged at the bottom of immersion bath 13 and serving to heat heating medium 12.

First, as shown in FIG. 3B, the panel module in a state where circuit board 4 is attached to chassis member 2 is held by holder 10, and immersed into heating medium 12, having previously been heated to a predetermined temperature, in immersion bath 13. In the case of immersing the panel module into heating medium 12, the panel module is positioned with respect to the top surface of heating medium 12 such that PDP 1 and joint member 3 are immersed into heating medium 12, and immersion is then performed. After the immersion, PDP 1 and joint member 3 are heated to a high temperature in a short time, and joining strength of joint member 3 decreases due to this heating, thereby leading to separation of PDP 1 from chassis member 2 with circuit board 4.

At this time, heat transmitted to chassis member 2 at the time of heating is conducted from chassis member 2 to holder 10 via thermally conductive elastic body 10a and dissipated, whereby it is possible to reduce a thermal load to circuit board 4 and the like due to radiation heat from chassis member 2. This eliminates the need for previously removing circuit board 4 from chassis member 2, and further allows an appropriate removal processing to be performed in a post-process without having an adverse effect due to heat on the attached components. In addition, in immersion bath 13, heating medium 12 is forcibly stirred, or the panel module is swayed or moved in some other way, thereby to enhance a heating effect.

As shown in FIG. 3C, after immersion of the panel module into heating medium 12, joint member 3 and PDP 1 are separated from chassis member 2.

Herein, as heating medium 12, there are for example used a thermally conductive particles containing ceramic particles or the like, a melted metal such as solder, a solution such as oil or an organic solvent. These are put into immersion bath 13 as a heat-resistant container, heated by heating means 14, and then used. Further, a heating temperature is, for example, set to at least not lower than the order of 200° C. at which the joining strength of joint member 3 is decreased. However, a margin of the heating temperature may be decided in consideration of a temperature decrease or natural cooling of heating medium 12 or the like in the case of immersing a heated matter.

Further, holder 10 holds the end of the panel module in a state where thermally conductive elastic body 10a is in contact with chassis member 2. Lifting means 11 then performs an up-and-down operation, to immerse the panel module held by holder 10 into heating medium 12.

As thus described, according to the present embodiment, in the disassembly process for the display device, immersing the whole of joint member 3 into heated heating medium 12 allows a temperature rise in the whole of joint member 3 in a uniform and rapid manner, so as to separate PDP 1 as a glass component and chassis member 2 in a short time.

Further, at the time of separation, heat is dissipated from chassis member 2 via holder 10, thereby allowing reduction in thermal load from chassis member 2 on circuit board 4 due to radiation heat. This eliminates the need for previously removing circuit board 4 from chassis member 2, and further allows reduction in adverse effect due to heat on a component attached to circuit board 4.

Accordingly, even in the case of a large-screen, large-sized display device, a panel and a chassis member can be separated in a short time, so as to realize efficient disassembly of the display device.

### INDUSTRIAL APPLICABILITY

The present disclosure is useful in promoting recycling of a large-screen, large-sized display device.

### REFERENCE MARKS IN THE DRAWINGS

1 PDP

2 chassis member

3 joint member

4 circuit board

10 holder

11 lifting means

12 heating medium

13 immersion bath

14 heating means

1. A disassembly method for a display device having a panel module in which a panel is joined to a support member by a joint member and a circuit board is disposed on a rear side of the support member,
the disassembly method comprising:
immersing the joint member of the panel module into a heated heating medium with the panel module being held by a holder including a heat radiating material;
heating the joint member while heat transmitted to the support member at the time of heating is conducted to the holder and dissipated; and
then separating the panel and the support member.

2. A disassembly device for a display device having a panel module in which a panel is joined to a support member by a joint member and a circuit board is disposed on a rear side of the support member,
the disassembly device comprising:
a holder made of a heat radiating material and serving to hold a panel module;
lifting means for moving up and down the holder;
an immersion bath, inside which a heating medium is housed; and
heating means disposed at a bottom of the immersion bath and serving to heat the heating medium,
wherein the joint member of the panel module is immersed into a heated heating medium with the panel module being held by the holder, and
the joint member is heated in the heating medium while heat transmitted to the support member at the time of heating is conducted to the holder and dissipated.
